(19) United States
(12) Patent Application Publication
(10) Pub. No.: US 2025/0351294 A1
(43) Pub. Date: Nov. 13, 2025

(54) AUXILIARY COOLING UNIT INCLUDING A THERMOELECTRIC COOLER AND AUXILIARY FLUID CHANNELS

(71) Applicant: Lenovo Enterprise Solutions (Singapore) Pte Ltd., Singapore (SG)

(72) Inventors: Tianyi Gao, Greensboro, NC (US); Yong Huang, Beijing (CN); Guodong Jiang, Beijing (CN)

(21) Appl. No.: 19/049,916

(22) Filed: Feb. 10, 2025

Related U.S. Application Data
(63) Continuation of application No. PCT/CN2024/092544, filed on May 11, 2024.

(51) Int. Cl. H05K 7/20; G06F 1/20; H10N 10/10

(52) U.S. Cl. CPC H05K 7/20254; G06F 1/20; H05K 7/20272; H05K 7/20281; H10N 10/10

(57) ABSTRACT

An apparatus includes auxiliary cooling units coupled to a connection bridge, where each auxiliary cooling unit includes a thermoelectric cooler and auxiliary fluid channels. The connection bridge includes fluid and power connections to external fluid and power sources, and distributed the fluid and power to each auxiliary unit. The cold side of the thermoelectric cooler is positioned in thermal contact with a main fluid cooling plate that cools an electronic component and the auxiliary fluid channels pass over the hot side of the thermoelectric cooler for circulating the cooling fluid to remove heat from the hot side of the thermoelectric cooler. A method includes circulating a cooling fluid through the main fluid cooling plate to remove heat from the electronic component, monitoring a performance metric of the electronic component, and varying an amount of electrical current passing through a thermoelectric cooler responsive to the performance metric of the electronic component.

### BACKGROUND

The present disclosure relates to apparatus and methods for cooling an electronic device, such as an integrated circuit.

### BACKGROUND OF THE RELATED ART

Processors, memory modules and other electronic components in a server or other computer use electrical power to perform the tasks of executing instructions and storing data. Unfortunately, in the process of performing these and other tasks, electronic components will generate heat. In some computers or servers, air circulation is sufficient to maintain the temperature of the electronic components in a desired range. However, some electronic components, such as a graphics processing unit, may produce so much heat that forced air is insufficient. So, some servers may provide fluid cooling plates in thermal contact with certain electronic components so that those electronic components do not experience temperatures that will damage the components.

### BRIEF SUMMARY

Some embodiments provide an apparatus comprising one or more auxiliary cooling units and a connection bridge. Each auxiliary cooling unit includes a thermoelectric cooler and auxiliary fluid channels, wherein the thermoelectric cooler has electrical connections for passing electrical current through the thermoelectric cooler to transfer heat from a cold side of the thermoelectric cooler to a hot side of the thermoelectric cooler, wherein the cold side of the thermoelectric cooler is in thermal contact with a main fluid cooling plate that cools an electronic component, and wherein the auxiliary fluid channels pass over the hot side of the thermoelectric cooler for circulating the cooling fluid to remove heat from the hot side of the thermoelectric cooler. The connection bridge includes external fluid supply and return connectors for connecting to an external fluid system, an external electrical power connector for connecting to an external power source, one or more internal sets of fluid supply and return connectors, and one or more internal electrical power connectors, wherein each internal set of fluid supply and return connectors are connectable to the auxiliary fluid channels of one of the one or more auxiliary cooling units, and wherein each of the internal electrical power connectors are connectable to the thermoelectric cooler of one of the one or more auxiliary cooling units.

Some embodiments provide a method comprising circulating a cooling fluid through a main fluid cooling plate to remove heat from an electronic component that is in thermal contact with the main fluid cooling plate, monitoring a performance metric of the electronic component, and varying an amount of electrical current passing through a thermoelectric cooler responsive to the performance metric of the electronic component, wherein the thermoelectric cooler has a cold side disposed in thermal contact with the main fluid cooling plate in alignment with the electronic component.

### BRIEF DESCRIPTION OF THE SEVERAL VIEWS OF THE DRAWINGS

FIG. 1 is a schematic diagram of two auxiliary cooling units coupled to a connection bridge.

FIG. 2 is a top view of two auxiliary cooling units in thermal contact with main fluid cooling plates arranged to cool electronic components installed on two peripheral devices (i.e., expansion card).

FIG. 3 is a schematic diagram illustrating a controller that controls the main fluid cooling plate and the thermoelectric cooler based upon the temperature and performance metric, respectively, of the electronic component.

FIG. 4A is a side view of an expansion card, such as an advanced PCIE device packaging, having auxiliary fluid connectors and an auxiliary power connector.

FIG. 4B is a side view of the expansion card of FIG. 4A after the auxiliary fluid connectors and the auxiliary power connector have been connected to an auxiliary cooling unit.

FIG. 5A is an end view of a server having four expansion cards having an electronic component and a main fluid cooling plate, where a connection bridge with four auxiliary cooling units is positioned to provide auxiliary cooling of the electronic components.

FIG. 5B is a top view of the server in FIG. 5A illustrating the connection bridge in fluid communication with auxiliary fluid ports and a source of direct current.

FIGS. 6A-B are end views of an auxiliary cooling unit secured in thermal contact with a main fluid cooling plate using screws and straps, respectively.

### DETAILED DESCRIPTION

Some embodiments provide an apparatus comprising one or more auxiliary cooling units and a connection bridge. Each auxiliary cooling unit includes a thermoelectric cooler and auxiliary fluid channels, wherein the thermoelectric cooler has electrical connections for passing electrical current through the thermoelectric cooler to transfer heat from a cold side of the thermoelectric cooler to a hot side of the thermoelectric cooler, wherein the cold side of the thermoelectric cooler is in thermal contact with a main fluid cooling plate that cools an electronic component, and wherein the auxiliary fluid channels pass over the hot side of the thermoelectric cooler for circulating the cooling fluid to remove heat from the hot side of the thermoelectric cooler. The connection bridge includes external fluid supply and return connectors for connecting to an external fluid system, an external electrical power connector for connecting to an external power source, one or more internal sets of fluid supply and return connectors, and one or more internal electrical power connectors, wherein each internal set of fluid supply and return connectors are connectable to the auxiliary fluid channels of one of the one or more auxiliary cooling units, and wherein each of the internal electrical power connectors are connectable to the thermoelectric cooler of one of the one or more auxiliary cooling units.

The electronic component may be any type of electronic component that generates heat as a byproduct of its operation. The embodiments may be implemented in information technology equipment, such as computers, servers and switches where there are various electronic components that generate heat. For example, the electronic components may be integrated circuits, such as a central processing unit (CPU), graphics processing unit (GPU), application specific integrated circuit (ASIC), system on a chip (SoC), and/or a memory device. Embodiments may be used to cool any number of electronic components of various types arranged in a variety of configurations. In one option, the electronic components are installed on one or more expansion cards that are themselves installed in expansion bus slots on a main system board.

Embodiments of the auxiliary cooling unit are particularly well-suited to be used in association with those electronic components that may experience temporary periods of high performance that could cause the electronic component to experience performance-limiting, damaging, or unsafe temperatures. In particular, the auxiliary cooling unit provides the technical benefit of being able to provide rapid cooling of the electronic component in response to high levels of performance that are known to result in the production of significant heat. Although a main fluid cooling plate may be a primary source of cooling for the electronic component, the main fluid cooling plate may either have insufficient cooling capacity or insufficient responsiveness to prevent the electronic component from reaching an undesired temperature. For example, a flow rate of cooling fluid circulating through the main fluid cooling plate may not increase until a high level of performance has already begun to raise the temperature of the electronic component above some predetermine temperature setpoint. By contrast, an auxiliary cooling unit of the disclosed embodiments may begin cooling the electronic component in response to an increase in the level of performance of the electronic component regardless of whether the electronic component experiences an increase in temperature. The auxiliary cooling unit is preferably positioned on the main cooling plate in alignment with the electronic component so that it cools the main cooling plate in the region aligned with the electronic component.

Some embodiments may further comprise one or more main fluid cooling plates including, for each of the one or more auxiliary cooling units, the main fluid cooling plate that is in thermal contact with the cold side of the thermoelectric cooler of the auxiliary cooling unit. For each of the one or more main fluid cooling plates, the main fluid cooling plate has a first side positionable in thermal communication with an electronic component, a second side opposite the first side, and main fluid channels disposed between the first and second sides for circulating a cooling fluid to remove heat from the electronic component. Specifically, each main fluid cooling plate may have its own set of cooling fluid supply and return connections to a source of cooling fluid.

The thermoelectric cooler (TEC) is a solid-state active heat pump that utilizes the Peltier effect to transfer heat from one side (a “cold side”) of the device to the other side (a “hot side”) with the consumption of electrical energy. Without limitation, a thermoelectric cooler may be formed with alternative p-type and n-type semiconductor pillars that a placed thermally in parallel to each other and electrically in series, and further including a thermally conducting and electrically insulating plate on each side. When a voltage is applied to the free ends of the two semiconductors there is a flow of direct current across the junction of the semiconductors, causing a temperature difference. The cold side absorbs heat which is then transported by the semiconductors to the hot side of the device.

The auxiliary fluid channels in each auxiliary cooling unit may include any number of channels and form any path or layout. In one example, the auxiliary fluid channels may follow a single serpentine path from an inlet port to an outlet port, where the serpentine path is spread out over a substantial portion of the hot side of the thermoelectric cooler. In another example, the auxiliary fluid channels may an inlet manifold channel along one edge that is connected to an inlet port, an outlet manifold channel along an opposing edge that is connected to an outlet port, and a plurality of parallel channels that extend between the inlet manifold channel and the outlet manifold channel to cover a substantial portion of the hot side of the thermoelectric cooler. The auxiliary fluid channels may be integrally formed to the hot side of the thermoelectric cooler or the auxiliary fluid channels may be included in an auxiliary fluid cooling plate that is secured to the hot side of the thermoelectric cooler. In one option, the auxiliary fluid channels of the auxiliary cooling unit may receive the cooling fluid through connectors on the expansion card, and the thermoelectric cooler may receive electrical power from other connectors on the expansion card.

In some embodiments, the one or more auxiliary cooling units are a plurality of auxiliary cooling units. Accordingly, the connection bridge will include a plurality of internal sets of fluid supply and return connectors and a plurality of internal electrical power connectors. Each auxiliary cooling unit will be connected to one internal set of fluid supply and return connectors of the connection bridge and one internal electrical power connector. Therefore, the connection bridge provides all of the connections necessary to support the operations of each auxiliary cooling unit, including the provision of electrical power to the thermoelectric cooler, the supply of cooling fluid to the auxiliary fluid channels, and the return of cooling fluid from the auxiliary fluid channels.

Some embodiments may further comprise a plurality of main fluid cooling plates. Each of the main fluid cooling plates will have a first side positionable in thermal communication with an electronic component, a second side opposite the first side, and main fluid channels disposed between the first and second sides for circulating a cooling fluid to remove heat from the electronic component. For each of the auxiliary cooling units, the cold side of the thermoelectric cooler is disposed in thermal contact with the second side of one of the main fluid cooling plates. It should be recognized that the auxiliary cooling units are not in thermal contact with the electronic components. Rather, it is the main fluid cooling plates that are in thermal contact with the electronic components. Electronic components that may at least temporarily produce more heat than the main fluid cooling plate can remove or increase performance faster than the main fluid cooling plate can respond may be cooled by a combination of a main fluid cooling plate and an auxiliary cooling unit.

In some embodiments, a first one of the main fluid cooling plates may be in thermal communication with first and second electronic components. Optionally, a first one of the auxiliary cooling units may be positioned in thermal contact with the first main fluid cooling plate and aligned with the first electronic component but not aligned with the second component. Accordingly, the auxiliary cooling unit is positioned to indirectly cool the first electronic component. The amount of electrical current passed through the thermoelectric cooler of the first auxiliary cooling unit may be varied responsive to a performance metric of the first electronic component. Therefore, a temporary increase in the performance metric may cause the thermoelectric cooler to turn on and provide cooling to the electronic component to which the auxiliary cooling unit is aligned. Subsequently, a drop in the performance metric may cause the thermoelectric cooler to turn off and no longer provide cooling to the electronic component.

In some embodiments, a controller may be used to monitor the performance metric of the electronic component and vary an amount of the electrical current that passes through the thermoelectric cooler responsive to the value of the performance metric of the electronic component. For example, the controller may be a dedicated controller, a service processor on a main system board where the electronic components are installed, or a central processing unit of a node where the electronic components are installed. The performance metric may vary according to the device type of the electronic component. In one instance, the electronic component may be a processor and the performance metric may be a rate of instructions executed, such as a number of instructions per second. Optionally, the controller may be the same controller that controls a flow rate or cooling fluid temperature for the main fluid cooling plate. Furthermore, a flow rate of cooling fluid circulating through the main fluid cooling plate may be controlled responsive to a temperature of the electronic component that is in thermal contact with the main fluid cooling plate. Accordingly, the controller may be in communication with a temperature sensor on or in the electronic component and a performance monitoring process.

In some embodiments, the auxiliary cooling units may be physically connectable to the connection bridge at a fixed right angle to the connection bridge. For example, the connection bridge may include rigid pipe or reinforced tubing that positions connectors at a right angle to the connection bridge. When the inlet and outlet ports of the auxiliary cooling units are connected to the connectors on the rigid pipe, the auxiliary cooling units are held at a fixed right angle to the connection bridge. In one implementation, the connection bridge may position multiple auxiliary cooling units to be in thermal contact with main fluid cooling plates on separate expansion cards, which expansion cards may be adjacent cards or cards separated by other cards or components. In an alternative implementation, the connection bridge may position multiple auxiliary cooling units to be in thermal contact with main fluid cooling plates on the same expansion card. Still further, the connection bridge may position auxiliary cooling units so that multiple auxiliary cooling units are in thermal contact with main fluid cooling plates on the same expansion card and multiple auxiliary cooling units are also in thermal contact with main fluid cooling plates on multiple expansion cards.

In some embodiments, the auxiliary cooling units may be physically secured in thermal contact with the main fluid cooling plate using one or more fasteners, such as screws, elastic straps or clips. For example, the main fluid cooling plate may have a plurality of threaded holes positioned adjacent to a perimeter edge of the plate and facing perpendicular to the plate. A set of screws may extend through holes in the auxiliary cooling units and then threadably engage the threaded holes in the main fluid cooling plate. Tightening the screws will then pull the auxiliary cooling unit into thermal contact with the main fluid cooling plate with or without any thermally conductive grease or a thermally conductive pad therebetween. Alternatively, opposing ends of an auxiliary cooling unit may be strapped or clipped together with opposing ends of the main fluid cooling plate or the expansion card itself.

Although an auxiliary cooling unit may be of sufficient size to be disposed in alignment with multiple electronic components, the auxiliary cooling units of some embodiments may each be disposed in alignment with a separate electronic component. In one example, the separate electronic components may be installed on separate expansion cards that are installed on a single system board. In order to supply cooling fluid and electrical power to auxiliary cooling units aligned with separate electronic components on separate expansion cards, the connection bridge may be positionable over a distal edge (upper edge) of one or more of the separate expansion cards to dispose each auxiliary cooling unit in alignment with the separate electronic component. Optionally, for each auxiliary cooling unit disposed to cool one of the separate electronic components, the amount of electrical current passed through the thermoelectric cooler of the auxiliary cooling unit may be varied responsive to a performance metric of the separate electronic component. So, each auxiliary cooling unit may be independently controlled to respond to the performance of the electronic component with which the auxiliary cooling unit is aligned. In one specific example, the separate electronic component is a processor and the performance metric is a rate of instruction execution. Where independent control of each auxiliary cooling unit is desired, the connection bridge should have separate control lines for each auxiliary cooling unit. Optionally, the electrical power lines to multiple auxiliary cooling units may pass through the same or separate connectors. However, where independent control is not required, the connection bring may connect to one external electrical power supply line and supply the same amount of electrical power or current to each of the auxiliary cooling units that are connected to the connection bridge. For example, two auxiliary cooling units on the same connection bridge may be aligned for cooling separate electronic components, but may receive the same electrical power in response to either of the two electronic components having a performance metric that indicates auxiliary cooling is needed.

Some embodiments provide a method comprising circulating a cooling fluid through a main fluid cooling plate to remove heat from an electronic component that is in thermal contact with the main fluid cooling plate, monitoring a performance metric of the electronic component, and varying an amount of electrical current passing through a thermoelectric cooler responsive to the performance metric of the electronic component, wherein the thermoelectric cooler has a cold side disposed in thermal contact with the main fluid cooling plate in alignment with the electronic component. Specifically, the amount of electrical current passed through the thermoelectric cooler would be increased as the performance metric of the electrical component increases, such that additional cooling is provided when the electrical component is performing at a level that is expected to result in a rise in heat generation.

In some embodiments, the method may further comprise measuring a temperature of the electronic component and controlling a flow rate of the cooling fluid that is circulating through the main fluid cooling plate responsive to the temperature of the electronic component. Specifically, the cooling fluid flow rate may be increased as the temperature of the electronic component increases.

In some embodiments, the method may further comprise circulating cooling fluid through auxiliary cooling channels along a hot side of the thermoelectric cooler. The flow rate of the cooling fluid circulating through the auxiliary cooling channels may be fixed or variable, such as a flow rate that increases with an increasing performance metric of the electronic component.

The method embodiments may further include the use of any one or more feature of the apparatus embodiments. Similarly, any of the apparatus embodiments may be used in accordance with any of the method embodiments.

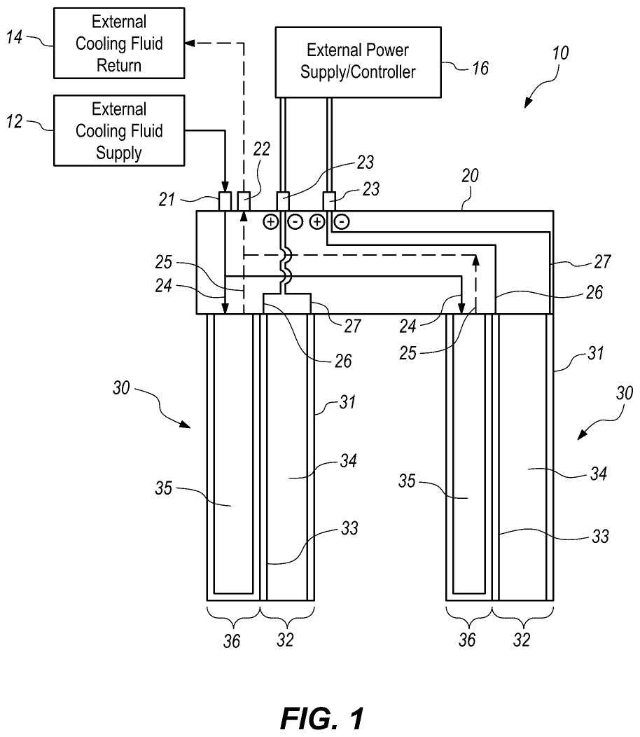

FIG. 1 is a schematic diagram of a system 10 including a connection bridge 20 operatively coupled to two auxiliary cooling units 30. The connection bridge 20 includes a pair of external fluid connectors (one fluid supply connector 21 and one fluid exhaust connector 22) and external power connectors 23 to be engaged with external sources. As shown, the external sources include an external cooling fluid supply 12, an external cooling fluid return 14, and an external power supply and controller 16. The connection bridge 20 also includes internal fluid supply ports 24, internal fluid return ports 25, and internal electrical connections 26, 27 that connect the one or more auxiliary cooling units 30 to the external cooling fluid and power sources. For example, the connection bridge 20 may serve as a manifold for the distribution of cooling fluid and electrical power to any number of auxiliary cooling units 30. However, the embodiment of FIG. 1 includes two external power connectors 23, wherein the connection bridge 20 directs electrical power from each external power connector 23 to a separate auxiliary cooling unit 30 such that the external power supply/controller 16 may independently control the amount of cooling provided by the auxiliary cooling units 30.

Each of the auxiliary cooling units 30 includes a thermoelectric cooler 32 that is used to cool an electronic component (not show), such as an integrated circuit or chip, or a memory module. The thermoelectric cooler 32 has a cold side/plate 31 and a hot side/plate 33 on opposing sides of a thermoelectric element 34 that may include an array of semiconductor pillars connected electrically in series, but thermally in parallel. The cold side 31 of the thermoelectric cooler 32 is positionable in direct thermal contact with a main fluid cooled plate (not shown) that is primarily responsible for maintaining the temperature of the electronic component and moves heat from the main fluid cooled plate to the hot side of the thermoelectric cooler The hot side 33 of the thermoelectric cooler 32 includes an auxiliary fluid cooled plate 36 with auxiliary fluid channels 35 for circulating cooling fluid to absorb and carry away heat.

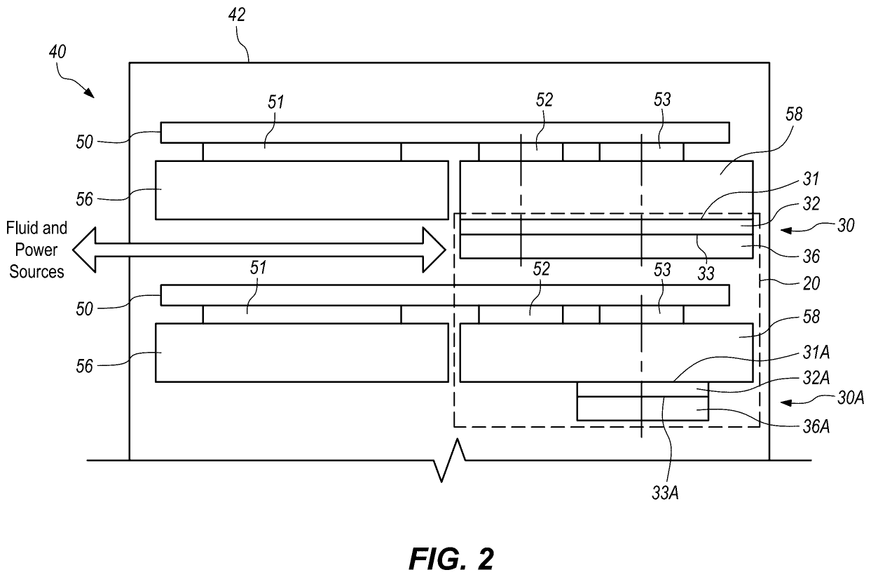

FIG. 2 is a top view of a computer system 40 including a main system board 24 with two expansion cards 50 installed in adjacent expansion bus slots. Each expansion card 50 includes various electronic components 51, 52, 53 that generate heat as a byproduct of their operation. A first main fluid cooled plate 56 is in thermal contact with the electronic component 51 and a second main fluid cooled plate 58 is in thermal contact with the electronic components 52, 53. In operation, a cooling fluid is circulated through fluid channels within the main fluid cooled plates 56, 58 so that the cooling fluid will absorb and carry off the heat. Furthermore, there is a space adjacent an exposed face 59 of the main fluid cooled plates 58 to provide an auxiliary cooling unit in thermal contact therewith.

Two auxiliary cooling units 30, 30A are in thermal contact with the main fluid cooling plates 58 that are arranged to cool the electronic components 52, 53 installed on the two expansion cards 50 (i.e., peripheral devices). The auxiliary cooling unit 30 includes a thermoelectric cooler 32 with a cold side in thermal contact with the main fluid cooling plate 58 and auxiliary cooling plate 36 formed along a hot side of the thermoelectric cooler 32.

The upper auxiliary cooling unit 30 has sufficient size to align with both of the electronic components 52, 53 on the upper expansion card 50. Accordingly, applying electrical power to the auxiliary cooling unit 30 will cause the cold side 31 to cool of the main fluid cooling plate 58 and both of the electronic components 52, 53. Heat that is moved through the thermoelectric cooler 32 from the cold side 31 to the hot side 33 is absorbed and carried off in cooling fluid that circulates through the auxiliary cooling plate 36.

The lower auxiliary cooling unit 30A is smaller than the upper auxiliary cooling unit 30 and is sized to align with only the electronic component 53 on the lower expansion card 50. Accordingly, applying electrical power to the lower auxiliary cooling unit 30A will cause the cold side 31A to cool that portion of the main fluid cooling plate 58 that is aligned with the electronic component 53. Heat that is moved through the thermoelectric cooler 32A from the cold side 31A to the hot side 33A is absorbed and carried off in cooling fluid that circulates through the auxiliary cooling plate 36A.

The two auxiliary cooling units 30, 30A are both coupled to the connection bridge 20 (the outline of which is shown in dashed lines). The connection bridge 20 will be configured consistent with FIG. 1 to include external fluid and power connections for connecting with fluid and power sources that are external to the connection bridge 20 as well as internal fluid and power connection for providing fluid and power to each of the auxiliary cooling units 30, 30A.

Note that the electronic component 51 on each expansion card 50 is cooled by a main fluid cooling plate 56, but no auxiliary cooling unit. This may be the case where the electronic component 51 has a fairly even level of performance and does not experience significant non-uniform power consumption that would cause undesirable temperature spikes. Accordingly, the electronic component 51 does not need the additional and rapid-response cooling that is provided by an auxiliary cooling unit. However, there is enough space for an auxiliary cooling unit to be positioned in alignment with the electronic components 51 and embodiments encompass the use of multiple auxiliary cooling units on a single expansion card.

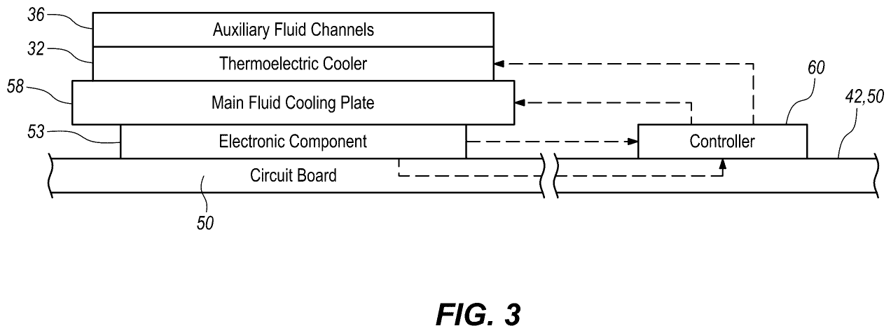

FIG. 3 is a schematic diagram illustrating a controller 60 that controls the main fluid cooling plate 58 and the thermoelectric cooler 32 based upon the temperature and performance metric, respectively, of the electronic component 53. In this illustration, the controller 60 may be a system controller, such as a baseboard management controller (BMC), installed on the main system board 42 or a separate controller installed on the expansion card 50 where the electronic component 53 is installed.

The controller 60 may monitor the temperature of the electronic component 53 and control an amount of cooling fluid circulated through the main fluid cooling plate 58 responsive to the temperature. Specifically, an increasing temperature of the electronic component may cause the controller 60 to increase a flow rate of cooling fluid circulated through the main fluid cooling plate 58. Control over the flow rate may be achieved, for example, by controlling a valve actuator so that the position of a valve element allows greater or lesser volumes of fluid through the valve and through the main fluid cooling plate. However, it may take some time for a sudden increase in the performance of the electronic component 53 to manifest into an increase in the temperature. Accordingly, the controller 60 may also control an amount of electrical power applied to the thermoelectric cooler 32. There is a technical benefit that the controller may increase cooling to the electronic component without waiting for the temperature of the electronic component to increase. Specifically, the controller may detect an increase in the performance (i.e., a performance metric) of the electronic component, immediately increase the electrical power applied to the thermoelectric cooler responsive to that detected performance increase, and thereby begin providing auxiliary cooling to the electronic component in anticipation of the heat that will be produced by the electronic component performing at the increased level. For example, where the electronic component is a processor, the performance metric may be an operating frequency such as a rate of instruction execution.

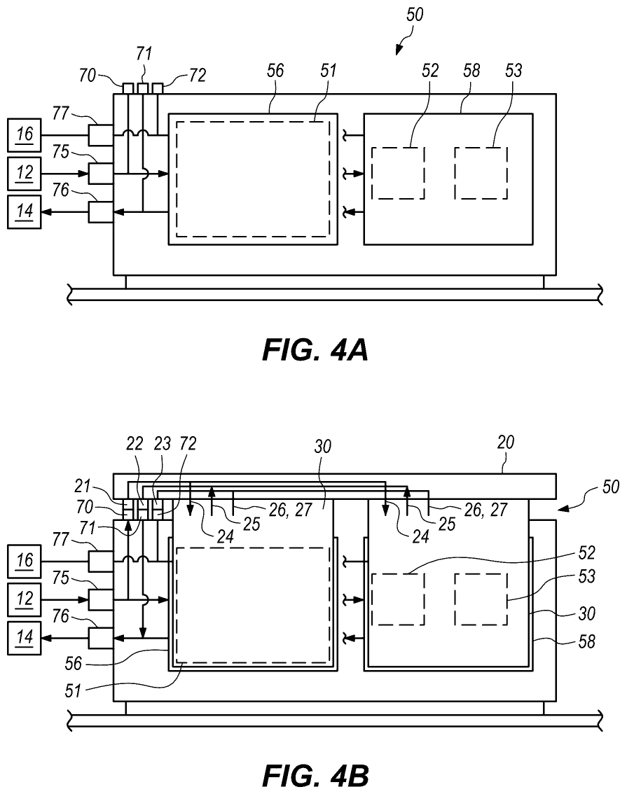

FIG. 4A is a side view or plan view of an expansion card 50, such as an advanced PCIE device packaging, having auxiliary fluid connectors 70, 71 and an auxiliary power connector 72 and supporting three electronic components 51, 52, 53. The expansion card 50 has main fluid connectors 75, 76 and main power connector 77 that receive fluid and power from the external sources 12, 14, 16. Internal fluid conduits then circulate fluid to and from the main fluid cooling plates 56, 58. Furthermore, the internal fluid conduits may branch to provide cooling fluid to the auxiliary fluid connectors 70, 71 and certain power lines through the power connector 77 may provide electrical power to the auxiliary power connector 72. While FIG. 4A does not show a connection bridge or any auxiliary cooling units, the expansion card 50 is designed to support the connections and operations of a connection bridge and auxiliary cooling units, as shown further in reference to FIG. 4B.

FIG. 4B is a side view of the expansion card 50 of FIG. 4A after connection of a connection bridge 20 with two auxiliary cooling units 30. The connection bridge 20 extends over the top of the expansion card 50 and has its external fluid supply connector 21 coupled to the auxiliary fluid supply connector 70, its external fluid return connector 22 coupled to the auxiliary fluid return connector 71, and its external power connector(s) 23 coupled to the auxiliary power connector 72. The connection bridge 20 also has fluid distribution lines and power distribution lines that extend from the connectors 21, 22, 23 to each of the auxiliary cooling units 30. Specifically, each of the auxiliary cooling units 30 will be connected to an internal fluid supply port 24, an internal fluid return port 25, and an internal electrical connection 26, 27. The electrical connections to the thermoelectric cooler 30 (not specifically shown) of each auxiliary cooling unit 30 may be independent electrical connections, which may be provided by multiple independent sets of electrical wires or conductors extending through the power connectors 77, 72, 23. Accordingly, the amount of cooling provided by each auxiliary cooling unit 30 may be independently controlled, such as according to the performance of the electronic components 51, 52, 53 that are disposed under (aligned with) the auxiliary cooling unit. However, the thermoelectric cooler of each auxiliary cooling unit may also be commonly controlled and receive the same electrical power or current. Optionally, these auxiliary cooling units may be collectively controlled to receive the same amount of electrical power or current responsive to the performance metric(s) of any or all of the electronic components 51, 52, 53. In other words, if any of the electronic components needs auxiliary cooling, then all of the electronic components will receive auxiliary cooling. It should be emphasized that the auxiliary cooling units 30 directly cool a respective one of the main fluid cooling plates 56, 58, which indirectly cools the respective electronic components 51,52, 53.

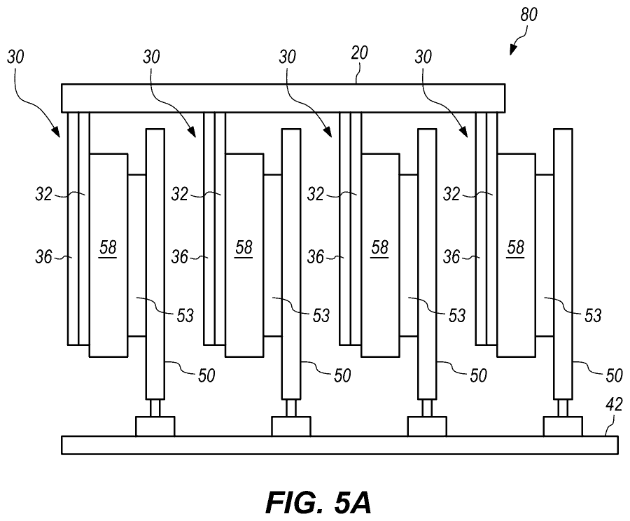

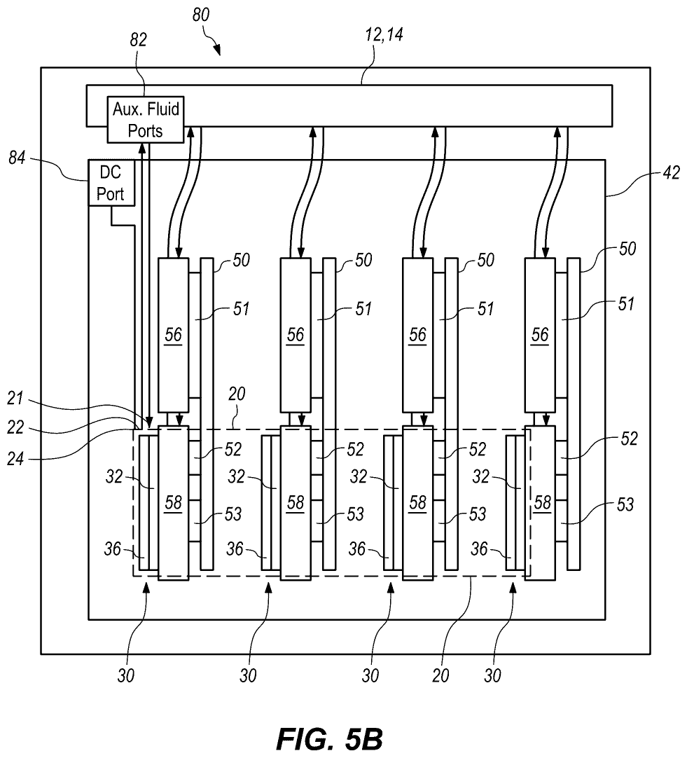

FIG. 5A is an end view of a server 80 having four expansion cards 50 installed on a main system board 42. Each expansion card 50 has an electronic component 53 installed on the card and there is a main fluid cooling plate 58 in thermal contact with the electronic component.

The connection bridge 20 extends over the top edge of the expansion cards 50 (over three of the four cards) and is connected with four auxiliary cooling units 30. The auxiliary cooling units 30 extend downward from the connection bridge 20 and positioned in thermal contact with the main fluid cooling plates 58 to provide auxiliary cooling of the electronic components 53. The amount of electrical power applied to the thermoelectric cooler 32 of each auxiliary cooling units 30 may be independently controlled responsive to a performance metric of the particular electronic component 53 that is cooled by that thermoelectric cooler. The heat that is moved from the cold side to the hot side of the thermoelectric cooler 32 is then removed in a cooling fluid circulated through the auxiliary fluid cooling plate or channels 36.

FIG. 5B is a top view of the server 80 in FIG. 5A illustrating the connection bridge 20 (outlined in dashed lines so other components can be seen) providing fluid and power from external sources to the four auxiliary fluid units 30. The external cooling fluid supply manifold 12 and external cooling fluid return manifold 14 are illustrated collectively and provide for cooling fluid circulation to each of the main fluid cooling plates 56, 58. However, the supply and return manifolds 12, 14 also provide auxiliary fluid ports 82 for connecting tubes that extend to the external fluid supply connector 21 and external fluid return connector 22 of the connection bridge 20. Similarly, a DC port 84 may be provided on the main system board 42 of the server 80 to provide electrical power through a power cable to the external power connector 23. The connection bridge 20 then provides fluid and power to each of the auxiliary cooling units 30, as previously described.

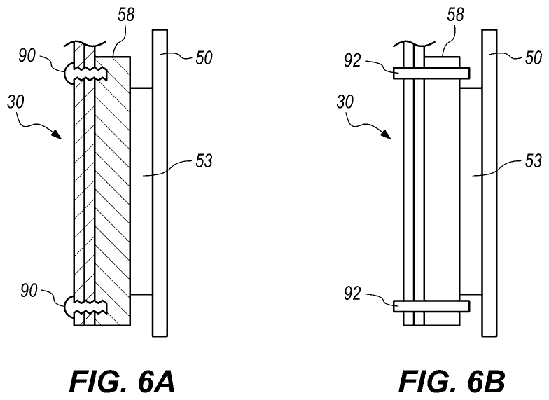

FIGS. 6A-B are end views of an auxiliary cooling unit 30 secured in thermal contact with a main fluid cooling plate using screws and straps, respectively. In FIG. 6A, a set of screws 90 may extend through the auxiliary cooling unit 30 and into the main fluid cooling plate 58 without interfering with any of the internal fluid channels within those members. Alternatively, in FIG. 6B, a pair of fasteners 92, such as elastic bands, straps or clips, may extend around the auxiliary cooling unit 30 and around one end the main fluid cooling plate 58 without interfering with the electronic component 53.

The terminology used herein is for the purpose of describing particular embodiments only and is not intended to limit the scope of the claims. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the embodiment.

The corresponding structures, materials, acts, and equivalents of all means or steps plus function elements in the claims below are intended to include any structure, material, or act for performing the function in combination with other claimed elements as specifically claimed. Embodiments have been presented for purposes of illustration and description, but it is not intended to be exhaustive or limited to the embodiments in the form disclosed. Many modifications and variations will be apparent to those of ordinary skill in the art after reading this disclosure. The disclosed embodiments were chosen and described as non-limiting examples to enable others of ordinary skill in the art to understand these embodiments and other embodiments involving modifications suited to a particular implementation.

What is claimed is:

1. An apparatus, comprising:
one or more auxiliary cooling units, each auxiliary cooling unit including:
a thermoelectric cooler and auxiliary fluid channels, wherein the thermoelectric cooler has electrical connections for passing electrical current through the thermoelectric cooler to transfer heat from a cold side of the thermoelectric cooler to a hot side of the thermoelectric cooler, wherein the cold side of the thermoelectric cooler is in thermal contact with a main fluid cooling plate that cools an electronic component, and wherein the auxiliary fluid channels pass over the hot side of the thermoelectric cooler for circulating the cooling fluid to remove heat from the hot side of the thermoelectric cooler; and
a connection bridge including external fluid supply and return connectors for connecting to an external fluid system, an external electrical power connector for connecting to an external power source, one or more internal sets of fluid supply and return connectors, and one or more internal electrical power connectors, wherein each internal set of fluid supply and return connectors are connectable to the auxiliary fluid channels of one of the one or more auxiliary cooling units, and wherein each of the internal electrical power connectors are connectable to the thermoelectric cooler of one of the one or more auxiliary cooling units.

2. The apparatus of claim 1, further comprising:
one or more main fluid cooling plates including, for each of the one or more auxiliary cooling units, the main fluid cooling plate that is in thermal contact with the cold side of the thermoelectric cooler of the auxiliary cooling unit, wherein, for each of the one or more main fluid cooling plates, the main fluid cooling plate has a first side positionable in thermal communication with an electronic component, a second side opposite the first side, and main fluid channels disposed between the first and second sides for circulating a cooling fluid to remove heat from the electronic component.

3. The apparatus of claim 1, wherein the one or more auxiliary cooling units are a plurality of auxiliary cooling units, and wherein the connection bridge includes a plurality of internal sets of fluid supply and return connectors and a plurality of internal electrical power connectors.

4. The apparatus of claim 3, further comprising:
a plurality of main fluid cooling plates, each of the main fluid cooling plates having a first side positionable in thermal communication with an electronic component, a second side opposite the first side, and main fluid channels disposed between the first and second sides for circulating a cooling fluid to remove heat from the electronic component, and wherein, for each of the auxiliary cooling units, the cold side of the thermoelectric cooler is in thermal contact with the second side of one of the main fluid cooling plates.

5. The apparatus of claim 4, wherein a first one of the main fluid cooling plates is in thermal communication with first and second electronic components, wherein a first one of the auxiliary cooling units is in thermal contact with the first main fluid cooling plate and aligned with the first electronic component and not aligned with the second component, and wherein the amount of electrical current passed through the thermoelectric cooler of the first auxiliary cooling unit is varied responsive to a performance metric of the first electronic component.

6. The apparatus of claim 1, wherein an amount of the electrical current passing through the thermoelectric cooler is varied responsive to a performance metric of the electronic component.

7. The apparatus of claim 6, wherein the electronic component is a processor and the performance metric is a number of instructions per second.

8. The apparatus of claim 6, wherein a flow rate of cooling fluid circulating through the main fluid cooling plate is controlled responsive to a temperature of the electronic component that is in thermal contact with the main fluid cooling plate.

9. The apparatus of claim 1, wherein the auxiliary fluid channels are included in an auxiliary fluid cooling plate secured to the hot side of the thermoelectric cooler.

10. The apparatus of claim 1, wherein the auxiliary cooling unit is positioned on the main cooling plate in alignment with the electronic component.

11. The apparatus of claim 10, wherein the electronic component is an integrated circuit secured to an expansion card installed on a system board.

12. The apparatus of claim 11, wherein the auxiliary cooling unit receives the cooling fluid and the electrical current through connectors on the expansion card.

13. The apparatus of claim 1, wherein each of the auxiliary cooling units are physically connectable to the connection bridge at a fixed right angle to the connection bridge.

14. The apparatus of claim 1, wherein each of the auxiliary cooling units are disposed to cool a separate electronic component, and wherein the separate electronic components are installed on separate expansion cards that are installed on a single system board.

15. The apparatus of claim 14, where the connection bridge is positionable over a distal edge of one or more of the separate expansion cards to dispose each auxiliary cooling unit in thermal contact with the separate electronic component.

16. The apparatus of claim 14, wherein, for each auxiliary cooling unit disposed to cool one of the separate electronic components, the amount of electrical current passed through the thermoelectric cooler of the auxiliary cooling unit is varied responsive to a performance metric of the separate electronic component.

17. The apparatus of claim 16, wherein the separate electronic component is a processor and the performance metric is a rate of instruction execution.

18. A method, comprising:
circulating a cooling fluid through a main fluid cooling plate to remove heat from an electronic component that is in thermal contact with the main fluid cooling plate;
monitoring a performance metric of the electronic component; and
varying an amount of electrical current passing through a thermoelectric cooler responsive to the performance metric of the electronic component, wherein the thermoelectric cooler has a cold side disposed in thermal contact with the main fluid cooling plate in alignment with the electronic component.

19. The method of claim 18, further comprising:
measuring a temperature of the electronic component; and
controlling a flow rate of the cooling fluid that is circulating through the main fluid cooling plate responsive to the temperature of the electronic component.

20. The method of claim 18, further comprising:
circulating cooling fluid through auxiliary cooling channels along a hot side of the thermoelectric cooler.
